(19) United States
(12) Patent Application Publication
(10) Pub. No.: US 2025/0357226 A1
(43) Pub. Date: Nov. 20, 2025

(54) CERAMIC SUBSTRATE AND MANUFACTURING METHOD THEREFOR

(71) Applicant: AMOGREENTECH CO., LTD., Gimpo-si, Gyeonggi-do (KR)

(72) Inventor: Jihyung LEE, Gimpo-si (KR)

(73) Assignee: AMOGREENTECH CO., LTD., Gimpo-si, Gyeonggi-do (KR)

(21) Appl. No.: 18/871,099

(22) PCT Filed: May 15, 2023
(86) PCT No.: PCT/KR2023/006531

§ 371 Date: Dec. 2, 2024

(30) Foreign Application Priority Data
May 31, 2022 (KR) 10-2022-0066936
May 31, 2022 (KR) 10-2022-0067150

(51) Int. Cl. H01L 23/13; H01L 21/48; H01L 23/15; H01L 23/538

(52) U.S. Cl. CPC H01L 23/13; H01L 21/486; H01L 21/4875; H01L 23/15; H01L 23/5384; H01L 23/5386

(57) ABSTRACT

The present invention relates to a ceramic substrate and a manufacturing method therefor, the ceramic substrate comprises: a ceramic base; a first electrode pattern and a second electrode pattern formed on the upper and lower surfaces of the ceramic base; a third electrode pattern which is formed on the upper surface of the ceramic base while being spaced apart from the first electrode pattern, wherein the first electrode pattern is configured to have a power semiconductor chip mounted thereon and the third electrode pattern may be configured to have a driver IC chip mounted thereon.

### TECHNICAL FIELD

The present disclosure relates to a ceramic substrate and a method of manufacturing the same, and more specifically, to a ceramic substrate and a method of manufacturing the same, in which a drive circuit is implemented on a ceramic substrate for a power module to enable miniaturization.

### BACKGROUND ART

Power semiconductor chips are responsible for basic parts of electronic systems as rectifiers and switches and include diodes, transistors, thyristors, and the like. In addition, IC integrated circuits have been developed with the advancement of a drive IC technology, and these IC integrated circuits can process high-voltage and high-current signals compared to voltages and currents of general digital or analog ICs.

In the case of power modules, high efficiency, miniaturization, and heat dissipation performance are emerging as competitiveness depending on the usage environment from high-voltage and high-current semiconductor chips. In general, since power inverters or motor drive circuit devices for electric vehicles, home appliances, multi-function printers, refrigerators, and washing machines are used separately due to the characteristics of different circuits and elements, there are problems that it is difficult to implement a lot of performance due to limitations in the volume and size of the module and miniaturization is not easy.

The matters described above in the background art are intended to help understanding of the background of the disclosure and may include matters not related to the known related art.

### SUMMARY OF INVENTION

### Technical Problem

The present disclosure has been made in efforts to solve the above problems and is directed to providing a ceramic substrate and a method of manufacturing the same, in which a semiconductor device part and drive circuit for a power module, or general control drive IC parts are applied on one substrate to enable high efficiency and miniaturization.

### Solution to Problem

A ceramic substrate according to an embodiment of the present disclosure for achieving the above object may include a ceramic base, a first electrode pattern and a second electrode pattern that are formed on upper and lower surfaces of the ceramic base, and a third electrode pattern formed to be spaced apart from the first electrode pattern on the upper surface of the ceramic base, wherein the first electrode pattern may be formed so that a power semiconductor chip is mounted thereon, and the third electrode pattern may be formed so that a drive integrated circuit (IC) chip is mounted thereon.

A portion of the upper surface of the ceramic base may be formed with a stepped surface recessed downward, and the first electrode pattern may be formed on the stepped surface. Here, a depth of the portion of the upper surface of the ceramic base recessed downward may be the same as a thickness of the first electrode pattern.

The upper surface of the ceramic base may be partitioned into a first region and a second region at both sides based on a virtual bisector, and the first electrode pattern may be disposed in the first region, and the third electrode pattern is disposed in the second region.

The first region and the second region may be formed coplanarly, and an area of the first region may be formed larger than an area of the second region.

The first region may be located lower than the second region.

Meanwhile, the ceramic base may include a plurality of via holes formed to pass through upper and lower surfaces of the ceramic base, and a metal filler filling the via hole, and the second electrode pattern and the third electrode pattern may be formed in contact with exposed upper and lower surfaces of the metal filler.

A thickness of the first electrode pattern may be larger than a thickness of the third electrode pattern.

The second electrode pattern may be formed throughout the lower surface of the ceramic base to face the first electrode pattern and the third electrode pattern.

The first electrode pattern may have a plurality of electrodes disposed in a predetermined pattern.

A method of manufacturing a ceramic substrate may include providing a ceramic base, forming a first electrode pattern and a second electrode pattern on upper and lower surfaces of the ceramic base, and forming a third electrode pattern spaced apart from the first electrode pattern on the upper surface of the ceramic base, wherein the first electrode pattern may be formed so that a power semiconductor chip is mounted thereon, and the third electrode pattern may be formed so that a drive integrated circuit (IC) chip is mounted thereon.

The providing of the ceramic base may include forming a stepped surface recessed downward on a portion of the upper surface of the ceramic base, and the first electrode pattern may be formed on the stepped surface.

The providing of the ceramic base may further include forming a plurality of via holes passing through the upper and lower surfaces of the ceramic base, filling the via hole with a metal filler, and firing.

The second electrode pattern and the third electrode pattern may be formed in contact with exposed upper and lower surfaces of the metal filler.

In the forming of the stepped surface, a depth of the portion of the upper surface of the ceramic base recessed downward may be the same as a thickness of the first electrode pattern.

In the forming of the first electrode pattern and the second electrode pattern, the first electrode pattern and the second electrode pattern may be formed of a metal foil and brazing-bonded to the upper and lower surfaces of the ceramic base.

The forming of the third electrode may include forming the third electrode pattern by screen-printing a conductive paste. The forming of the third electrode pattern may include forming the third electrode pattern by a thin film process.

The forming of the third electrode pattern may further include firing. Here, the firing may perform a firing process at a temperature in the range of 350° C. to 600° C.

### Advantageous Effects of Invention

According to the present disclosure, the semiconductor device part and drive circuit for a power module, or general control drive IC parts can be implemented on one surface, thereby achieving high efficiency, miniaturization, and lightweight.

In addition, according to the present disclosure, the substrate and drive IC for a power module has a dual in line (DIL) structure that is an integrated hybrid structure and can be used in any field from electronic parts to an energy field.

In addition, according to the present disclosure, by forming the third electrode pattern, which is thinner than the first electrode pattern and formed in a fine pattern, using a screen printing method, it is possible to automatically correct the pattern location during printing and print the precise pattern.

In addition, according to the present disclosure, when a combination of the voltages, currents, and signals of the second electrode pattern formed on the lower surface of the ceramic base and the third electrode pattern on which the drive IC chip is mounted is needed, the second electrode pattern and the third electrode pattern can be connected by the metal filler filling the via hole, thereby increasing the movement efficiency of the current and achieving the miniaturization of the power module.

In addition, according to the present disclosure, since the first electrode pattern may be formed on the stepped surface of a portion of the upper surface of the ceramic base recessed downward, even when the first electrode pattern is formed thicker than the third electrode pattern, the height difference from the third electrode pattern can be reduced, thereby reducing the location adjustment time of the capillary during bonding to about ⅓.

### BRIEF DESCRIPTION OF DRAWINGS

FIG. 1 is a perspective view showing a ceramic substrate according to one embodiment of the present disclosure.

FIG. 2 is an exploded perspective view of the ceramic substrate according to one embodiment of the present disclosure.

FIG. 3 is a plan view showing the ceramic substrate according to one embodiment of the present disclosure.

FIG. 4 is a cross-sectional view along line a-a′ in FIG. 3.

FIG. 5 is an enlarged plan view of area A in FIG. 3.

FIG. 6 is a side view showing a state in which a power semiconductor chip and a drive IC chip are mounted on the ceramic substrate according to one embodiment of the present disclosure and a wire is connected.

FIG. 7 is an exploded perspective view of a ceramic substrate according to another embodiment of the present disclosure.

FIG. 8 is a plan view showing the ceramic substrate according to another embodiment of the present disclosure.

FIG. 9 is a cross-sectional view along line a-a′ in FIG. 8.

FIG. 10 is an enlarged plan view of area A′ in FIG. 8.

FIG. 11 is a side view showing a state in which a power semiconductor chip and a drive IC chip are mounted on the ceramic substrate according to another embodiment of the present disclosure and a wire is connected.

FIG. 12 is a partial perspective view showing a state in which a drive IC chip is mounted on the ceramic substrate according to another embodiment of the present disclosure and a wire is connected.

FIG. 13 is a flowchart for describing a method of manufacturing a ceramic substrate according to one embodiment of the present disclosure.

FIG. 14 is a view for describing the method of manufacturing a ceramic substrate according to one embodiment of the present disclosure.

FIG. 15 is a view for describing a method of manufacturing a ceramic substrate according to another embodiment of the present disclosure.

### DESCRIPTION OF EMBODIMENTS

Hereinafter, exemplary embodiments of the present disclosure will be described with reference to the accompanying drawings.

The embodiments are provided to more completely describe the present disclosure to those skilled in the art, and the following embodiments may be modified in various different forms, and the scope of the present disclosure is limited to the following embodiments. Rather, the embodiments are provided to make the disclosure more faithful and complete and fully convey the spirit of the present disclosure.

Terms used herein are intended to describe specific embodiments and are not intended to limit the present disclosure. In addition, in the present specification, singular forms may include plural forms unless the context clearly indicates otherwise.

In the description of the embodiments, when each layer (film), area, pattern, or structure is described as being formed “on” or “under” a substrate, each layer (film), area, pad, or patterns, “on” and “under” include both cases of being formed “directly” or “indirectly with other elements interposed therebetween.” In addition, in principle, the reference for “above” or “under” each layer are based on the drawing.

The drawings are only intended to help understanding of the spirit of the present disclosure and should not be construed as limiting the scope of the present disclosure by the drawings. In addition, in the drawings, a relative thickness and length, or a relative size may be exaggerated for convenience and clarity of description.

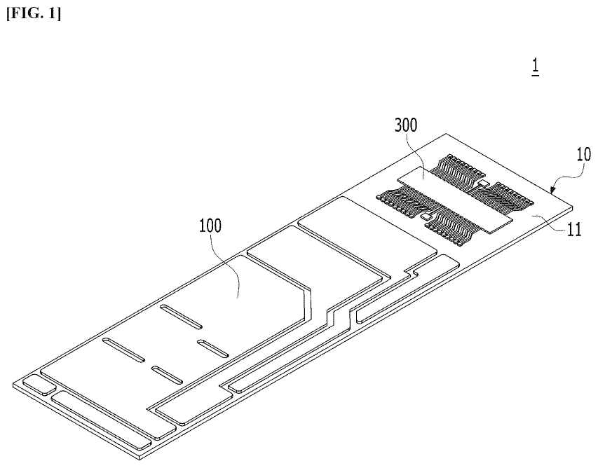

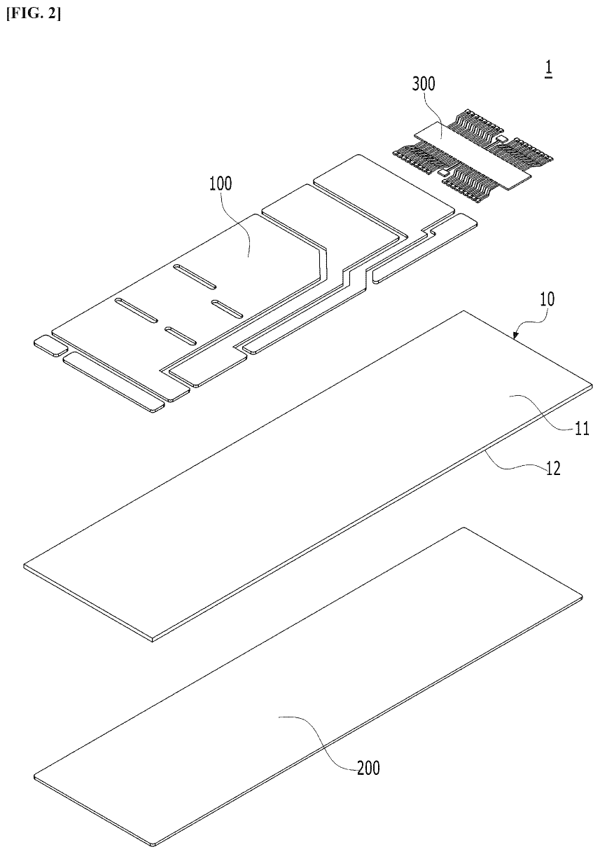

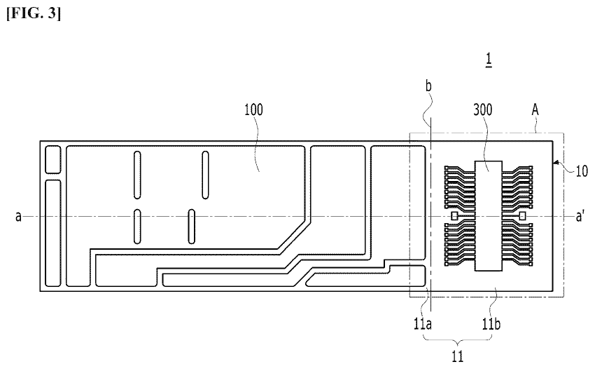

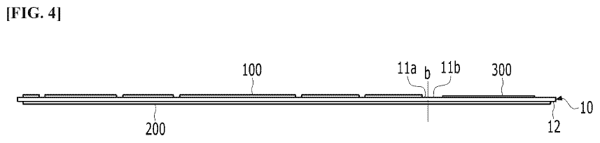

FIG. 1 is a perspective view showing a ceramic substrate according to one embodiment of the present disclosure, FIG. 2 is an exploded perspective view of the ceramic substrate according to one embodiment of the present disclosure, FIG. 3 is a plan view showing the ceramic substrate according to one embodiment of the present disclosure, and FIG. 4 is a cross-sectional view along line a-a′ in FIG. 3.

As shown in FIGS. 1 to 4, a ceramic substrate 1 according to one embodiment of the present disclosure may include a ceramic base 10, a first electrode pattern 100, a second electrode pattern 200, and a third electrode pattern 300.

The ceramic base 10 may be, for example, one of alumina (Al₂O₃), AlN, SiN, and Si₃N₄. A thickness of the ceramic base 10 ranges from 0.3 mm to 0.4 mm. For example, the thickness of the ceramic base 10 may be provided to range from 0.32 mm or 0.38 mm.

The first electrode pattern 100 and the second electrode pattern 200 may be formed on upper and lower surfaces 11 and 12 of the ceramic base 10. In addition, the third electrode pattern 300 may be formed to be spaced apart from the first electrode pattern on the upper surface 11 of the ceramic base 10. Specifically, the upper surface of the ceramic base 10 may be partitioned into a first region 11a and a second region 11b at both sides based on a virtual bisector b (see FIGS. 3 and 4). Here, the first region 11a and the second region 11b may be formed coplanarly. In addition, an area of the first region 11a may be formed larger than an area of the second region 11b. The first electrode pattern 100 may be disposed in the first region 11a, and the third electrode pattern 300 may be disposed in the second region 11b.

The first electrode pattern 100 and the second electrode pattern 200 may be formed of a metal foil and brazing-bonded to the upper surface 11 and lower surface 12 of the ceramic base 10, and may be formed as electrode patterns by subsequent etching, machining, or the like. For the brazing bonding, a brazing bonding layer made of an alloy material including at least one of Ag, AgCu, and AgCuTi may be used. The heat treatment for brazing may be performed at a temperature in the range of 780° C. to 900° C. Such a ceramic substrate 1 is referred to as an active metal brazing (AMB) substrate, and such an AMB substrate has excellent durability and heat dissipation performance. Although the present embodiment describes the AMB substrate as an example, a direct bonding copper (DBC) substrate and a thick printing copper (TPC) substrate may be applied.

Although the present embodiment describes an example in which the second electrode pattern 200 is formed in a flat shape, the present disclosure is not limited thereto, and the second electrode pattern 200 may be formed in the form of a circuit pattern according to a semiconductor chip, product specifications, or the like. The first electrode pattern 100 and the second electrode pattern 200 may be made of one of Cu, a Cu alloy (CuMo or the like), and Al as an example.

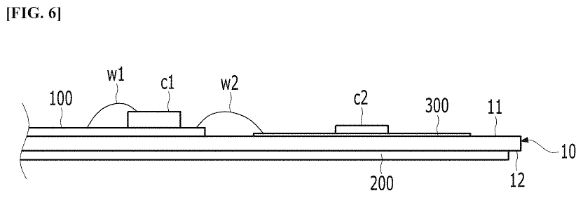

The first electrode pattern 100 may be formed so that a power semiconductor chip c1 (see FIG. 6) is mounted thereon. For example, the first electrode pattern 100 may be provided with a SiC and GaN-based power semiconductor chip c1 that may respond to requirements such as a high voltage, a high current, a high temperature operation, use and high-speed switching in a high frequency environment, minimizing power loss, and a small chip size. The first electrode pattern 100 may be provided with any element such as not only SiC chips and GaN chips, but also Si chips, metal oxide semiconductor field effect transistors (MOSFETs), insulated gate bipolar transistors (IGBTs), junction field effect transistors (JFET), high electric mobility transistors (HEMT), and diodes. The first electrode pattern 100 may have a plurality of electrodes disposed in a predetermined pattern.

The third electrode pattern 300 may be configured so that a drive IC chip c2 (see FIG. 6) is mounted thereon. For example, the third electrode pattern 300 may be provided with a silicon on insulator (SOI)-based driving, electrical, and electronic control element. The third electrode pattern 300 may be made of one of Ag, Au, Pt, Cu, an Ag alloy, and carbon black.

Since the first electrode pattern 100 may be a part which is formed so that a power semiconductor chip c1 is mounted thereon and through which a large current flows and the third electrode pattern 300 may be a part which is formed so that the drive IC chip c2 is mounted and through which a small current flows, the thickness of the first electrode pattern 100 may be formed larger than the thickness of the third electrode pattern 300. For example, the thickness of the first electrode pattern 100 may be about 0.3 mm, and the thickness of the third electrode pattern 300 may be about 20 μm, but the present disclosure is not limited thereto.

The second electrode pattern 200 may be formed in a wide area throughout the lower surface 12 of the ceramic base 10 to facilitate heat transfer. The second electrode pattern 200 may have one region facing the first electrode pattern 100 and the other region facing the third electrode pattern 300.

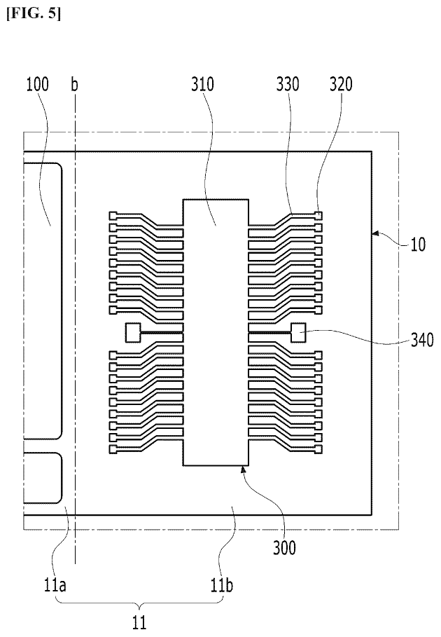

FIG. 5 is an enlarged plan view of area A in FIG. 3, and FIG. 6 is a side view showing a state in which a power semiconductor chip and a drive IC chip are mounted on the ceramic substrate according to one embodiment of the present disclosure and a wire is connected.

As shown in FIG. 5, the third electrode pattern 300 may include a first pattern region 310 formed so that the drive IC chip c2 is mounted thereon, a second pattern region 320 to which one end of a second wire w2 is bonded, a third pattern region 330 connecting the first pattern region 310 to the second pattern region 320, and a fourth pattern region 340 formed to extend from the center of the first pattern region 310 to both sides. Here, a plurality of second pattern regions 320 may be disposed at both sides of the first pattern region 310, and the third pattern region 330 may extend a predetermined length to both sides to connect the first pattern region 310 to the second pattern region 320.

As shown in FIG. 6, the power semiconductor chip c1 may be bonded to the first electrode pattern 100 and connected to the first electrode pattern 100 by the first wire w1. Here, the first wire w1 may be an Al wire, but is not limited thereto. In addition, the drive IC chip c2 may be bonded to the first pattern region 310 of the third electrode pattern 300, and the second pattern region 320 of the third electrode pattern 300 may be connected to the first electrode pattern 100 by a second wire w2. Here, the second wire w2 may be made of Au, but is not limited thereto.

In this way, the ceramic substrate 1 according to one embodiment of the present disclosure is the ceramic substrate 1 having a dual electrode structure in which two functional chips, that is, the power semiconductor chip cl and the drive IC chip c2, are mounted on the upper surface 11 of the ceramic base 10. The ceramic substrate 1 having such a dual electrode structure has advantages that the size can be reduced, the weight can be reduced, heat dissipation efficiency can be increased, and any field such as home appliances and electric vehicle modules can be adopted compared to the case in which the drive IC module and the power module are separately provided.

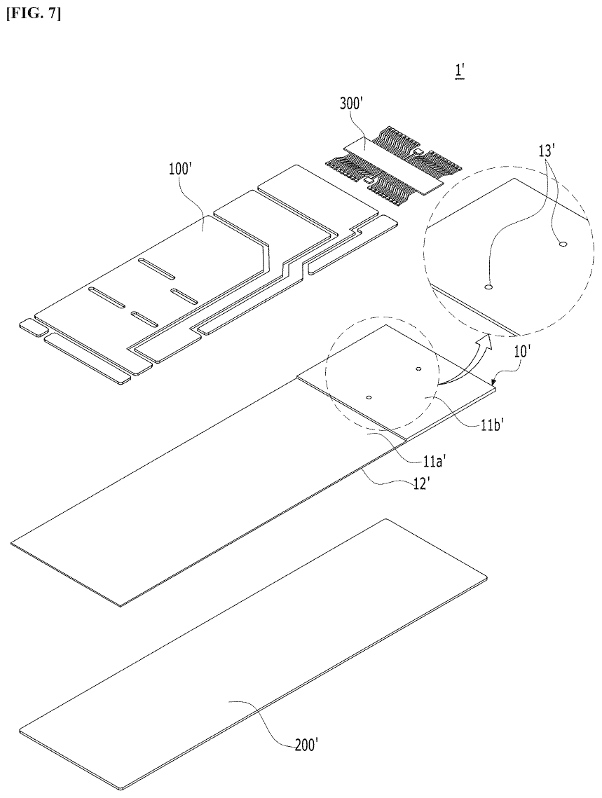

Hereinafter, a ceramic substrate according to another embodiment of the present disclosure will be described with reference to FIGS. 7 to 12. For convenience of description, the description of the same components as one embodiment shown in FIGS. 1 to 6 will be omitted, and differences will be mainly described below.

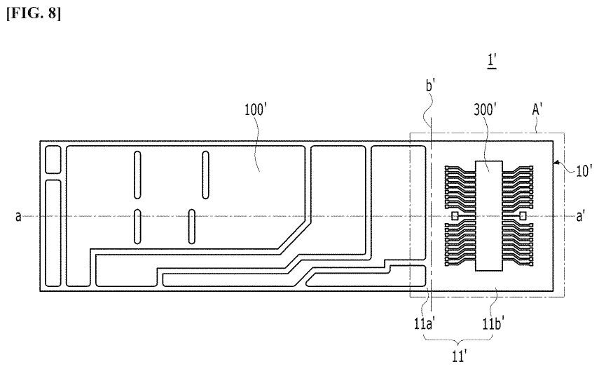

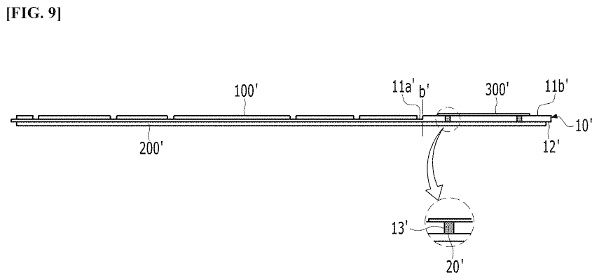

FIG. 7 is an exploded perspective view of a ceramic substrate according to another embodiment of the present disclosure, FIG. 8 is a plan view showing the ceramic substrate according to another embodiment of the present disclosure, and FIG. 9 is a cross-sectional view along line a-a′ in FIG. 8.

As shown in FIGS. 7 to 9, a ceramic substrate 1′ according to another embodiment of the present disclosure may include a ceramic base 10′, a first electrode pattern 100′, a second electrode pattern 200′, and a third electrode pattern 300′, in which an upper surface of the ceramic base 10′ may be partitioned into a first region 11a′ and a second region 11b′ at both sides based on a virtual bisector b′ (see FIGS. 8 and 9). Here, the first region 11a′ may be formed with a stepped surface recessed downward, located lower than the second region 11b′, and formed to have a larger area than the second region 11b′. The first electrode pattern 100′ may be disposed in the first region 11a′, and the third electrode pattern 300′ may be disposed in the second region 11b′.

In addition, the ceramic base 10′ may have a plurality of via holes 13′ formed to pass through upper and lower surfaces 11′ and 12′. The via holes 13′ may be filled with a metal filler 20′. The metal filler 20′ may be one of Ag, W, Mo, and an Ag alloy, but is not limited thereto. The metal filler 20′ filling the via hole 13′ may be fixed to the via hole 13′ through a sintering process and may electrically conduct the second electrode pattern 200′ and the third electrode pattern 300′ facing each other with the via hole 13′ interposed therebetween.

In the present embodiment, the number of via holes 13′ is 2 in total, but is not limited thereto. A diameter of the via hole 13′ is preferably formed in the range of 0.1 mm or more and 0.3 mm or less. When the diameter of the via hole 13′ is formed in the range of 0.1 mm or more and 0.3 mm or less, the metal filler 20′ may fill the via hole 13′ without voids. The diameter of the via hole 13′ may be formed to correspond to the thickness of the ceramic base 10′. For example, when the thickness of the ceramic base 10′ is 0.38 mm, the diameter of the via hole 13′ is preferably formed in the range of 0.1 mm or more and 0.2 mm or less correspondingly, and when the thickness of the via hole 13′ exceeds 0.2 mm, there may be problems that filling efficiency is lowered and the metal filler 20′ is discharged from the via hole 13′ after firing.

The second electrode pattern 200′ and the third electrode pattern 300′ may be formed in contact with exposed upper and lower surfaces of the metal filler 20′. The via hole 13′ is formed in a region in which the second electrode pattern 200′ faces the third electrode pattern 300′. Therefore, the second electrode pattern 200′ and the third electrode pattern 300′ may come into contact with the exposed upper and lower surfaces of the metal filler 20′ filling the via hole 13′. Since the ceramic base 10′ is made of an insulating material, the ceramic base 10′ has a structure in which the electrical connection of electrode patterns formed on the upper surface 11′ and the lower surface 12′ is impossible. Therefore, when a combination of voltages, currents, and signals of the second electrode pattern 200′ formed on the lower surface 12′ of the ceramic base 10′ and the third electrode pattern 300′ on which a drive IC chip c2′ is mounted are needed, the second electrode pattern 200′ and the third electrode pattern 300′ may be connected by the metal filler 20′ filling the via hole 13′, thereby increasing current flowing efficiency and achieving the miniaturization of the power module.

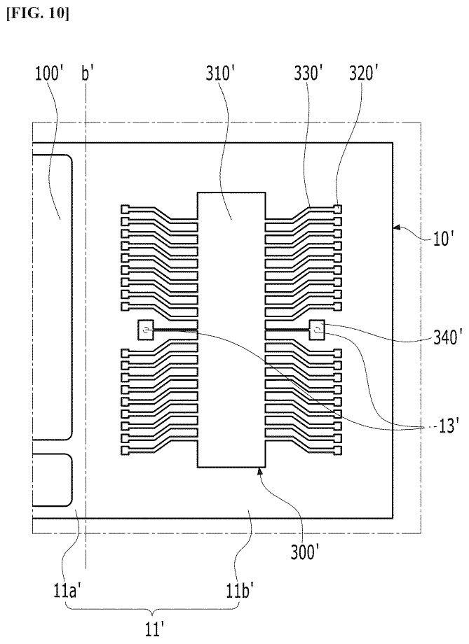

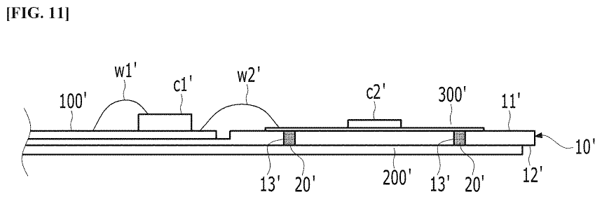

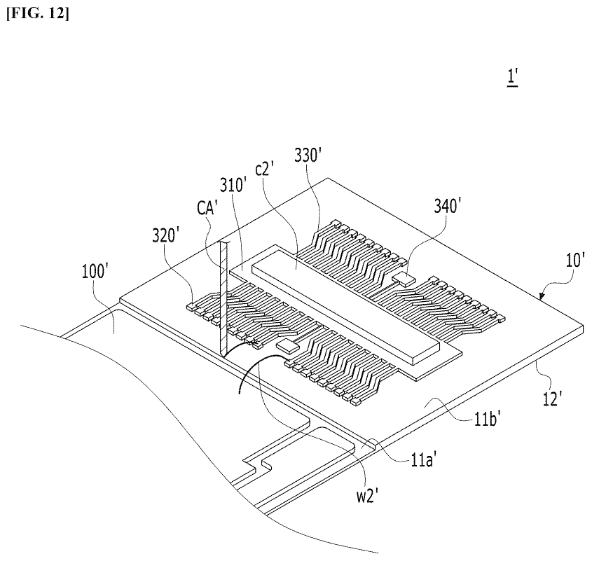

FIG. 10 is an enlarged plan view of area A′ in FIG. 8, FIG. 11 is a side view showing a state in which a power semiconductor chip and a drive IC chip are mounted on the ceramic substrate according to another embodiment of the present disclosure and a wire is connected, and FIG. 12 is a partial perspective view showing a state in which a drive IC chip is mounted on the ceramic substrate according to another embodiment of the present disclosure and a wire is connected.

As shown in FIG. 10, the third electrode pattern 300′ may include a first pattern region 310′ formed so that the drive IC chip c2′ is mounted thereon, a second pattern region 320′ to which one end of a second wire w2′ is bonded, a third pattern region 330′ connecting the first pattern region 310′ to the second pattern region 320′, and a fourth pattern region 340′ formed at a location corresponding to the via hole 13′.

Referring to FIG. 11, a power semiconductor chip c1′ may be bonded to the first electrode pattern 100′ and connected to the first electrode pattern 100′ by a first wire w1′.

In addition, the drive IC chip c2′ may be bonded to the first pattern region 310′ of the third electrode pattern 300′, and the second pattern region 320′ of the third electrode pattern 300′ may be connected to the first electrode pattern 100′ by the second wire w2′. Specifically, as shown in FIG. 12, in a state in which the drive IC chip c2′ is mounted on the first pattern region 310′ of the third electrode pattern 300′, the second pattern region 320′ of the third electrode pattern 300′ and the first electrode pattern 100′ may be connected by the second wire w2′ using a capillary CA′.

The capillary performing the wire bonding process may form a primary bonding portion at the top of the second pattern region 320′ of the third electrode pattern 300′, then move upward in a vertical direction, and then move to the first electrode pattern 100′ to form a secondary bonding portion. In this case, since the thickness of the third electrode pattern 300′ is about 20 μm, and the thickness of the first electrode pattern 100′ is about 0.3 mm, there is a height difference of about 280 μm. Therefore, since it takes time to adjust the upper and lower locations of the capillary, which are tailored to the thickness of the third electrode pattern 300′, to match the thickness of the first electrode pattern 100′, the manufacturing time increases accordingly and productivity is inevitably lowered.

To solve such a problem, according to another embodiment of the present disclosure, the ceramic substrate 1′ may have a portion of the upper surface 11′ of the ceramic base 10′ formed in a stepped manner, thereby reducing the height difference between the first electrode pattern 100′ and the third electrode pattern 300′. Specifically, when the upper surface 11′ of the ceramic base 10′ is partitioned into the first region 11a′ and the second region 11b′ based on the virtual bisector b′ (see FIGS. 8 and 9), the first region 11a′ may be formed with a stepped surface recessed downward. Here, the first electrode pattern 100′ may be formed on the stepped surface of the first region 11a′ recessed downward. Therefore, even when the first electrode pattern 100′ is formed thicker than the third electrode pattern 300′, the height difference from the third electrode pattern 300′ formed in the second region 11b′ not recessed can be reduced. In this case, a depth of a portion of the upper surface of the ceramic base 10′ recessed downward may be the same as the thickness of the first electrode pattern 100′. In this way, by reducing the height difference between the first electrode pattern 100′ and the third electrode pattern 300′, it is possible to reduce the location adjustment time of the capillary to about ⅓.

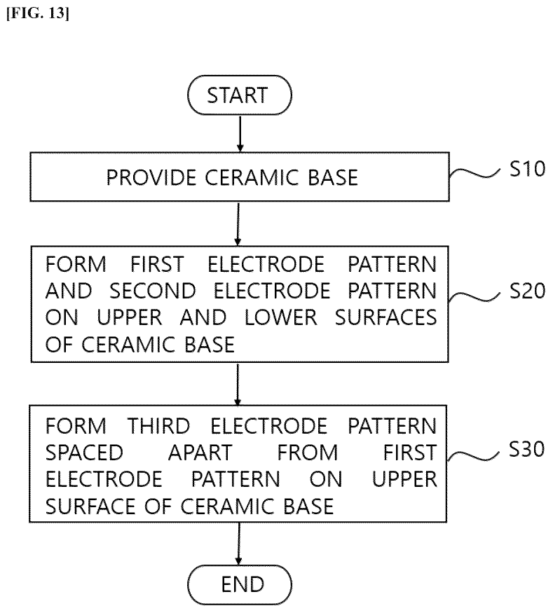

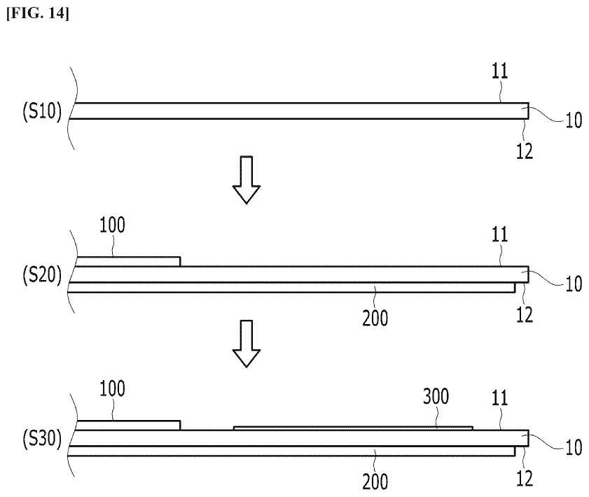

Hereinafter, a method of manufacturing a ceramic substrate according to one embodiment of the present disclosure will be described with reference to FIGS. 13 and 14.

FIG. 13 is a flowchart for describing a method of manufacturing a ceramic substrate according to one embodiment of the present disclosure, and FIG. 14 is a view for describing the method of manufacturing a ceramic substrate according to one embodiment of the present disclosure.

As shown in FIGS. 13 and 14, the method of manufacturing a ceramic substrate according to one embodiment of the present disclosure may include an operation S10 of providing the ceramic base 10, an operation S20 of forming the first electrode pattern 100 and the second electrode pattern 200 on the upper and lower surfaces 11 and 12 of the ceramic base 10, and an operation S30 of forming the third electrode pattern 300 spaced apart from the first electrode pattern 100 on the upper surface of the ceramic base 10.

The operation S10 of providing the ceramic base 10 is provided using any one of alumina (Al₂O₃), AlN, SiN, and Si₃N₄. The thickness of the ceramic base 10 ranges from 0.3 mm to 0.4 mm. For example, the thickness of the ceramic base 10 may be provided to range from 0.32 mm or 0.38 mm.

The operation S20 of forming the first electrode pattern 100 and the second electrode pattern 200 on the upper and lower surfaces 11 and 12 of the ceramic base 10 may include forming the first electrode pattern 100 on the first region 11a of the upper surface 11 of the ceramic base 10 and forming the second electrode pattern 200 on the lower surface 12 of the ceramic base 10.

In the operation S20 of forming the first electrode pattern 100 and the second electrode pattern 200, the first electrode pattern 100 and the second electrode pattern 200 may be formed of a metal foil and brazing-bonded to the upper surface 11 and the lower surface 12 of the ceramic base 10. For the brazing bonding, a brazing bonding layer made of an alloy material including at least one of Ag, AgCu, and AgCuTi may be used. The heat treatment for brazing may be performed at a temperature in the range of 780° C. to 900° C. The first electrode pattern 100 and the second electrode pattern 200 may be made of one of Cu, a Cu alloy (CuMo or the like), and Al as an example.

The operation S30 of forming the third electrode pattern 300 spaced apart from the first electrode pattern 100 on the upper surface of the ceramic base 10 may include forming the third electrode pattern 300 by printing a conductive paste using a screen printing method. Since the third electrode pattern 300 is formed as a fine pattern having a line and space shape in the range of 100 um to 150 um, the third electrode pattern 300 is preferably formed by printing the conductive paste using the screen printing method. Since the reference of the line and space is thickness, the line and space shape of the third electrode pattern 300 formed thinner than the first electrode pattern 100 is finer than that of the first electrode pattern 100. To precisely implement such a fine pattern, the screen printing method is preferred. The screen printing method is suitable for forming a fine pattern because it has a fast curing speed and excellent adhesiveness and flexibility. In addition, when a table on which a product is seated under a screen mask and a screen process is performed, a program may automatically correct the location of the table through a reference index hole at the side while performing printing, thereby printing the precise pattern at the correct location.

Meanwhile, in the operation S30 of forming the third electrode pattern 300 spaced apart from the first electrode pattern 100 on the upper surface of the ceramic base 10, the third electrode pattern 300 may be formed by a thin film process. In the thin film process, a metal thin film is formed by a method such as deposition, coating, or application, and then a pattern of a desired shape may be formed using a pattern mask. The thin film process may be used when forming a fine pattern having the line and space shape of 15 μm to 30 μm to a thickness of up to 2 μm.

Meanwhile, the operation S30 of forming the third electrode pattern 300 may further include firing. That is, in the operation S30 of forming the third electrode pattern 300, a firing process may be performed at a temperature in the range of 350° C. to 600° C. to reinforce the bonding strength of the screen-printed conductive paste or the thin film layer formed by the thin film process. In this case, the firing process may be performed in a reducing atmosphere or an oxidizing atmosphere.

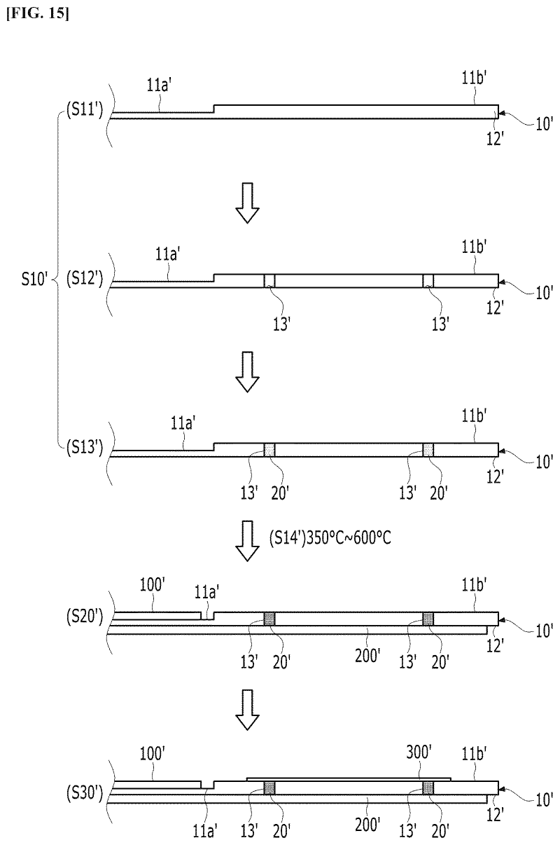

Hereinafter, a method of manufacturing a ceramic substrate according to another embodiment of the present disclosure will be described with reference to FIG. 15.

FIG. 15 is a view for describing a method of manufacturing a ceramic substrate according to another embodiment of the present disclosure.

As shown in FIGS. 15, the method of manufacturing a ceramic substrate according to another embodiment of the present disclosure may include, as in one embodiment, the operation S10 of providing the ceramic base 10, the operation S20 of forming the first electrode pattern 100 and the second electrode pattern 200 on the upper and lower surfaces 11 and 12 of the ceramic base 10, and the operation S30 of forming the third electrode pattern 300 spaced apart from the first electrode pattern 100 on the upper surface of the ceramic base 10.

Here, the operation S10 of providing the ceramic base 10 may include an operation S11 of forming a stepped surface recessed downward on a portion of the upper surface 11 of the ceramic base 10, an operation S12 of forming a plurality of via holes 13 passing through the upper and lower surfaces 11 and 12 of the ceramic base 10, an operation S13 of filling the via holes 13 with the metal filler 20, and an operation S14 of firing. In the operation S11 of forming the stepped surface, the depth of the portion of the upper surface 11 of the ceramic base 10 recessed downward may be the same as the thickness of the first electrode pattern 100.

The operation S12 of forming the plurality of via holes 13 passing through the upper and lower surfaces 11 and 12 of the ceramic base 10 may include forming the plurality of via holes 13 passing through the upper and lower surfaces 11 and 12 of the ceramic base 10 using a laser drilling method or a photo via method. The via hole 13 may be formed in an area in which the second electrode pattern 200 faces the third electrode pattern 300 to connect the second electrode pattern 200 to the third electrode pattern 300. In the present embodiment, the number of via holes 13 is 2 in total, but is not limited thereto.

A diameter of the via hole 13 is preferably formed in the range of 0.1 mm or more and 0.3 mm or less. When the diameter of the via hole 13 is formed in the range of 0.1 mm or more and 0.3 mm or less, the metal filler 20 may fill the via hole 13 without voids. The diameter of the via hole 13 may be formed to correspond to the thickness of the ceramic base 10. For example, when the thickness of the ceramic base 10 is 0.38 mm, the diameter of the via hole 13 is preferably formed in the range of 0.1 mm or more and 0.2 mm or less correspondingly, and when the thickness of the via hole 13 exceeds 0.2 mm, there may be problems that filling efficiency is lowered and the metal filler 20 is discharged from the via hole 13 after firing.

In the operation S13 of filling the via hole 13 with the metal filler 20, the metal filler 20 may fill the via hole 13 in the form of metal ink (paste). The metal filler 20 may be one of Ag, W, Mo, and an Ag alloy, but is not limited thereto.

In the firing operation S14, the metal filler 20 filling the via hole 13 may be fixed

to the via hole 13 through a drying and firing (sintering) process. The firing operation S14 may be performed at a temperature in the range of 350° C. to 600° C., but may be performed at any temperature depending on the metal filler 20.

Then, the operation S20 of forming the first electrode pattern 100 and the second electrode pattern 200 on the upper and lower surfaces 11 and 12 of the ceramic base 10 may include forming the first electrode pattern 100 on the first region 11a of the upper surface 11 of the ceramic base 10 and forming the second electrode pattern 200 on the lower surface 12 of the ceramic base 10. Here, the first electrode pattern 100 may be formed on the stepped surface of the first region 11a recessed downward. Therefore, even when the first electrode pattern 100 is formed thicker than the third electrode pattern 300, the height difference from the third electrode pattern 300 formed in the second region 11b not recessed can be reduced. In this case, a depth of a portion of the upper surface 11 of the ceramic base 10 recessed downward may be the same as the thickness of the first electrode pattern 100. In this way, by reducing the height difference between the first electrode pattern 100 and the third electrode pattern 300, it is possible to reduce the location adjustment time of the capillary to about ⅓ and increase productivity.

In the operation S20 of forming the first electrode pattern 100 and the second electrode pattern 200, the first electrode pattern 100 and the second electrode pattern 200 may be formed of a metal foil and brazing-bonded to the upper surface 11 and the lower surface 12 of the ceramic base 10. Meanwhile, after filling the via hole 13 of the ceramic base 10 with the metal filler 20 and drying the metal filler 20, a metal layer formed of a metal foil on the upper surface 11 and the lower surface 12 of the ceramic base 10 may be brazing-bonded. Here, the drying process may temporarily fix a state in which the metal filler 20 fills the via hole 13, and the metal filler 20 may be fired in the brazing bonding process to electrically conduct the second electrode pattern 200 and the third electrode pattern 300.

Then, the operation S30 of forming the third electrode pattern 300 spaced apart from the first electrode pattern 100 on the upper surface of the ceramic base 10 may include forming the third electrode pattern 300 by screen-printing the conductive paste or forming the third electrode pattern 300 by the thin film process.

The second electrode pattern 200 and the third electrode pattern 300 may be formed in contact with exposed upper and lower surfaces of the metal filler 20. The via hole 13 is formed in a region in which the second electrode pattern 200 faces the third electrode pattern 300. Therefore, the second electrode pattern 200 and the third electrode pattern 300 may come into contact with the exposed upper and lower surfaces of the metal filler 20 filling the via hole 13. Since the ceramic base 10 is made of an insulating material, the ceramic base 10 has a structure in which the electrical connection of electrode patterns formed on the upper surface 11 and the lower surface 12 is impossible. Therefore, when a combination of voltages, currents, and signals of the second electrode pattern 200 formed on the lower surface 12 of the ceramic base 10 and the third electrode pattern 300 on which a drive IC chip c2 is mounted are needed, the second electrode pattern 200 and the third electrode pattern 300 may be connected by the metal filler 20 filling the via hole 13, thereby increasing current flowing efficiency and achieving the miniaturization of the power module.

The above description is merely the exemplary description of the technical spirit of the present disclosure, and those skilled in the art to which the present disclosure pertains will be able to variously modify and change the present disclosure without departing from the essential characteristics of the present disclosure. Therefore, the embodiments disclosed in the present disclosure are not intended to limit the technical spirit of the present disclosure, but intended to describe the same, and the scope of the technical spirit of the present disclosure is not limited by these embodiments. The scope of the present disclosure should be construed by the appended claims, and all technical ideas within the equivalent scope should be construed as being included in the scope of the present disclosure.

1. A ceramic substrate comprising:
a ceramic base;
a first electrode pattern and a second electrode pattern that are formed on upper and lower surfaces of the ceramic base; and
a third electrode pattern formed to be spaced apart from the first electrode pattern on the upper surface of the ceramic base,
wherein the first electrode pattern is formed so that a power semiconductor chip is mounted thereon, and
the third electrode pattern is formed so that a drive integrated circuit (IC) chip is mounted thereon.

2. The ceramic substrate of claim 1, wherein a portion of the upper surface of the ceramic base is formed with a stepped surface recessed downward, and
the first electrode pattern is formed on the stepped surface.

3. The ceramic substrate of claim 2, wherein a depth of the portion of the upper surface of the ceramic base recessed downward is the same as a thickness of the first electrode pattern.

4. The ceramic substrate of claim 1, wherein the upper surface of the ceramic base is partitioned into a first region and a second region at both sides based on a virtual bisector, and
the first electrode pattern is disposed in the first region, and the third electrode pattern is disposed in the second region.

5. The ceramic substrate of claim 4, wherein the first region and the second region are formed coplanarly.

6. The ceramic substrate of claim 4, wherein an area of the first region is larger than an area of the second region.

7. The ceramic substrate of claim 4, wherein the first region is located lower than the second region.

8. The ceramic substrate of claim 1, wherein the ceramic base includes:
a plurality of via holes formed to pass through upper and lower surfaces of the ceramic base; and
a metal filler filling the via hole, and
the second electrode pattern and the third electrode pattern are formed in contact with exposed upper and lower surfaces of the metal filler.

9. The ceramic substrate of claim 1, wherein a thickness of the first electrode pattern is larger than a thickness of the third electrode pattern.

10. The ceramic substrate of claim 1, wherein the second electrode pattern is formed throughout the lower surface of the ceramic base to face the first electrode pattern and the third electrode pattern.

11. The ceramic substrate of claim 1, wherein the first electrode pattern has a plurality of electrodes disposed in a predetermined pattern.

12. A method of manufacturing a ceramic substrate, the method comprising:
providing a ceramic base;
forming a first electrode pattern and a second electrode pattern on upper and lower surfaces of the ceramic base; and
forming a third electrode pattern spaced apart from the first electrode pattern on the upper surface of the ceramic base,
wherein the first electrode pattern is formed so that a power semiconductor chip is mounted thereon, and
the third electrode pattern is formed so that a drive integrated circuit (IC) chip is mounted thereon.

13. The method of claim 12, wherein the providing of the ceramic base includes forming a stepped surface recessed downward on a portion of the upper surface of the ceramic base, and
the first electrode pattern is formed on the stepped surface.

14. The method of claim 13, wherein the providing of the ceramic base further includes:
forming a plurality of via holes passing through the upper and lower surfaces of the ceramic base;
filling the via hole with a metal filler; and
firing.

15. The method of claim 14, wherein the second electrode pattern and the third electrode pattern are formed in contact with exposed upper and lower surfaces of the metal filler.

16. The method of claim 13, wherein in the forming of the stepped surface, a depth of the portion of the upper surface of the ceramic base recessed downward is the same as a thickness of the first electrode pattern.

17. The method of claim 12, wherein in the forming of the first electrode pattern and the second electrode pattern, the first electrode pattern and the second electrode pattern are formed of a metal foil and brazing-bonded to the upper and lower surfaces of the ceramic base.

18. The method of claim 12, wherein the forming of the third electrode includes forming the third electrode pattern by screen-printing a conductive paste.

19. The method of claim 12, wherein the forming of the third electrode pattern includes forming the third electrode pattern by a thin film process.

20. The method of claim 12, wherein the forming of the third electrode pattern further includes firing, and
the firing performs a firing process at a temperature in the range of 350° C. to 600° C.
